(19) United States
(12) Patent Application Publication
(10) Pub. No.: US 2017/0115789 A1
(43) Pub. Date: Apr. 27, 2017

(54) TOUCH-SCREEN WITH FRONT-MOUNTED FLEXIBLE DISPLAY

(71) Applicant: L-3 COMMUNICATIONS CORPORATION, New York, NY (US)

(72) Inventors: Jerome CONWAY, Johns Creek, GA (US); Mark FLETCHER, Cumming, GA (US)

(73) Assignee: L-3 COMMUNICATIONS CORPORATION, New York, NY (US)

(21) Appl. No.: 15/400,380

(22) Filed: Jan. 6, 2017

Related U.S. Application Data
(63) Continuation of application No. 13/867,545, filed on Apr. 22, 2013.
(60) Provisional application No. 61/635,937, filed on Apr. 20, 2012.

(30) Foreign Application Priority Data
Apr. 22, 2013 (US) PCT/US13/37569

(51) Int. Cl. G06F 3/041; H01L 27/32; H01L 51/00; G06F 3/045

(52) U.S. Cl. CPC G06F 3/0412; G06F 3/0414; G06F 3/045; H01L 27/323; H01L 51/0097

(57) ABSTRACT

A display system includes a backing, a touch-screen, and a front-mounted flexible display. The backing provides a rigid substrate or base upon which the other components are mounted. The touch-screen includes a conductive rear panel and a conductive front panel separated from the rear panel by an insulating air gap. The front conductive panel is flexible enough and positioned close enough to the rear panel that touching the front panel causes enough deflection of the front panel to cause it to bridge the air gap locally and to contact the rear panel. Thus, in this way the electrical path (and therefore the resistance of the circuit) can be mapped to the particular location on the touch-screen touched by the user.

### CROSS-REFERENCE TO RELATED APPLICATION

This application is a continuation of U.S. Non-Provisional Patent Application 13/867,545 filed Apr. 22, 2013 and claims foreign priority to International Patent Application PCT/US13/37569 filed Apr. 22, 2013; which both claim the priority benefit of U.S. Provisional Patent Application 61/635,937 filed Apr. 20, 2012; which is hereby incorporated herein by reference.

### BACKGROUND

In the known use of touch-screens with displays, the touch-screen is mounted in front of the display. In this regard, the image or information displayed on the display is projected through the touch-screen. Unfortunately, this can cause degradation of the displayed image or information, depending upon the optical quality of the touch-screen.

Typical known pressure-sensitive touch-screens have a rear planar element and a front planar element spaced from the rear element by an insulating gap. The front planar element is somewhat flexible to the touch and the insulating gap is small in relation to this flexibility, such that when a person touches the front planar element it deflects enough to come into local contact with the rear planar element. The two elements are electrically conductive with known resistive paths associated with each touch location. Thus, by measuring the resistance (or voltage) of the circuit, one can determine where on the touch-screen has been touched by a user. Other pressure sensitive touch-screens are also known, but are not as commonly employed as the resistive touch-screen described above.

In order to provide this touch feature, it has been known to position the touch-screen in front of the display with nothing between the user and touch-screen so that this sensitivity can be exploited. As noted briefly above, this has the undesirable consequence of requiring that the touch-screen be made of materials with good optical properties lest optical quality of the image/information be compromised.

### SUMMARY OF THE INVENTION

Briefly described, in a first preferred form the present invention comprises a display system including a touch-screen and a thin, flexible display mounted in front of the touch-screen and being flexible enough to allow a user to touch the thin, flexible display and to operate the touch-screen behind the thin, flexible display. Preferably, the touch-screen is a pressure-sensitive touch-screen. Optionally, the touch-screen is mounted to a rigid backing and the thin, flexible display is mounted to the touch-screen.

In another example form the invention comprises a touch-screen display system including a touch-screen integrated with a thin, flexible display wherein a rear surface of the thin, flexible display serves as the front panel of the touch-screen, and wherein the thin, flexible display is mounted in front of the touch-screen rear panel and being flexible enough to allow a user to touch the thin, flexible display and to operate the touch-screen.

Optionally, the touch-screen is a pressure-sensitive touch-screen. Also optionally, when the flexible display serves as the front panel of the touch-screen, the rear surface of the thin, flexible display is separated from the touch-screen rear panel by an air gap.

Optionally, a transparent, flexible cover layer can be added to the front of the flexible display to provide protection from environments or damage, enhance optical characteristics, etc. This transparent cover layer can be constructed of flexible plastic, flexible glass, or any other suitable transparent flexible material. The transparent cover layer will preferably have a minimal thickness and stiffness so as not to substantially increase the force required by the user to activate the touch-screen.

### BRIEF DESCRIPTION OF THE DRAWING FIGURES

FIG. 1 is a schematic illustration of a typical prior art arrangement of a touch-screen in front of a display.

FIG. 2 is a schematic illustration of a touch-screen with a front-mounted flexible display according to a first example form of the present invention.

FIG. 3 is a schematic illustration of an alternative embodiment of a touch-screen with a front-mounted flexible display in which a rear surface of the flexible display is conductive and is used as the front element of the touch-screen.

### DETAILED DESCRIPTION OF THE EXAMPLE EMBODIMENTS

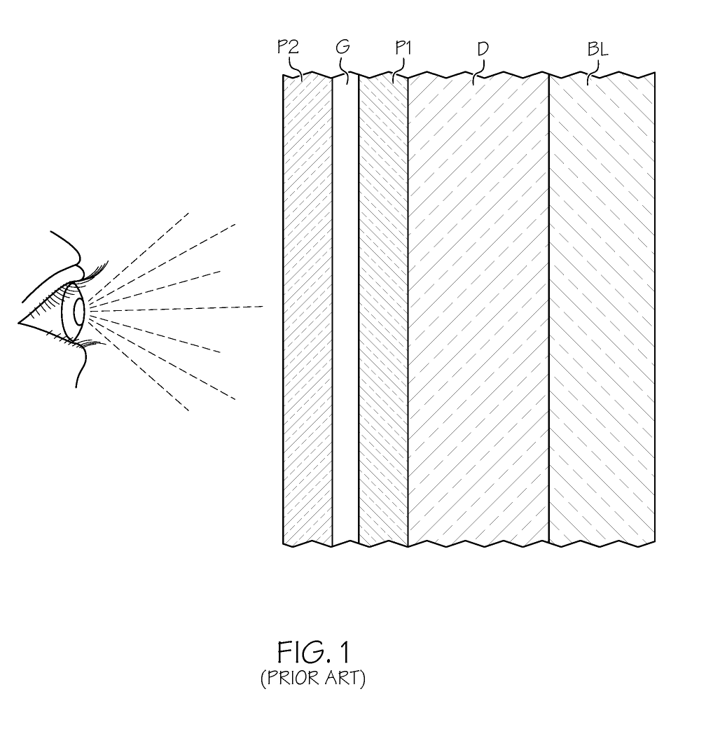

FIG. 1 shows the typical prior art arrangement of a touch screen in front of a display. As shown in this figure, in the known prior art arrangements, a display, such as an AMLCD display D, is mounted to a backlight BL. A touch-screen is mounted in front of the AMLCD D and comprises a rear resistive panel P1 and a front resistive panel P2 separated from the rear resistive panel by an insulating air gap G. The touch-screen is made with panels having good optical qualities. Thus, the user can see through the touch-screen to the AMLCD display D.

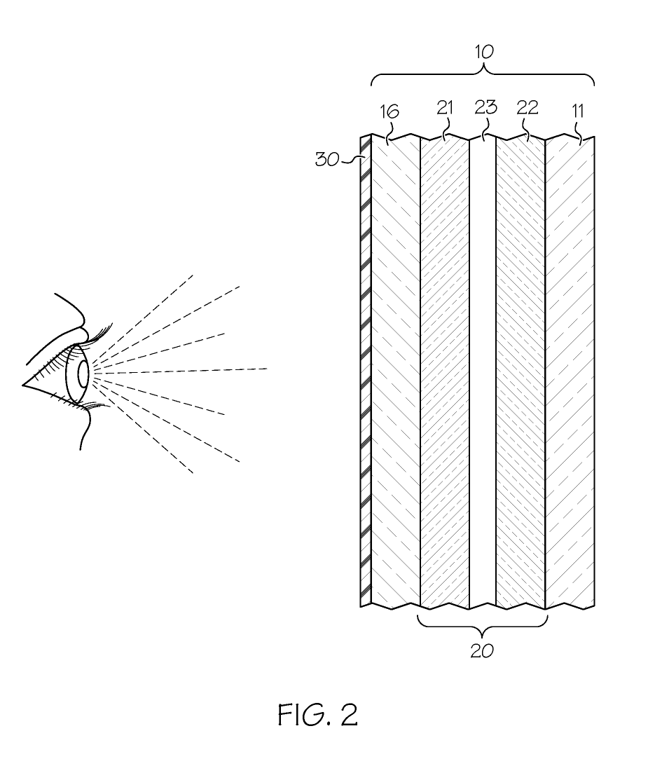

FIG. 2 shows a display system 10 including a backing 11, a touch-screen 20, and a front-mounted flexible display 16 according to a first example form of the present invention. The backing 11 provides a rigid substrate or base upon which the other components are mounted. The backing 11 preferably is opaque. The touch-screen 20 can be of various configurations. In the example shown, the touch-screen 20 is a resistive type. In this construction, the touch-screen includes a conductive rear panel 22 and a conductive front panel 21 separated from the rear panel by an insulating air gap 23. The front conductive panel 21 is flexible enough and positioned close enough to the rear panel 22 that touching the front panel 21 causes enough deflection of the front panel to cause it to bridge the air gap locally and to contact the rear panel 22. Thus, in this way the electrical path (and therefore the resistance of the circuit) can be mapped to the particular location on the touch-screen touched by the user.

The thin, flexible display 16 preferably is mounted directly in front of the front panel 21 of the touch-screen 20. In this regard, the display 16 can be bonded to the front panel 21. Alternatively, the display 16 can be mounted in other manners. Importantly, the display 16 is flexible enough to allow the user's touch to be communicated therethrough, causing the front panel 21 of the touch-screen 20 to contact the rear panel 22. Thus, the flexible display 16 does not interfere with the operation of the touch-screen. Advantageously, this allows the use of touch-screen components that need not have good optical properties (since the user doesn't need to see the touch-screen and no images need to be visible through the touch-screen). Thus, lower cost touch-screen components/technologies can be employed.

The thin, flexible display 16 preferably has a thickness of between about 0.10 mm and 1.0 mm. Moreover, preferably the thin, flexible display 16 has a stiffness (Young's modulus) of between about 60 Gpa and 195 Gpa. Optionally, the thin, flexible display 16 can be of metallic construction or metalized polymer construction. Other constructions of the thin, flexible display 16 can be utilized as well. One example of the thin, flexible display 16 that works well in this context is the flexible Organic (OLED) display made by Universal Display Corporation (UDC) of Ewing, N.J.

Optionally, as shown in FIG. 2, a transparent, flexible cover layer 30 can be added to the front of the flexible display to provide protection from environments or damage, enhance optical characteristics, etc. This transparent cover layer can be constructed of flexible plastic, flexible glass, or any other suitable transparent flexible material. The transparent cover layer preferably has a minimal thickness and stiffness so as not to substantially increase the force required by the user to activate the touch-screen.

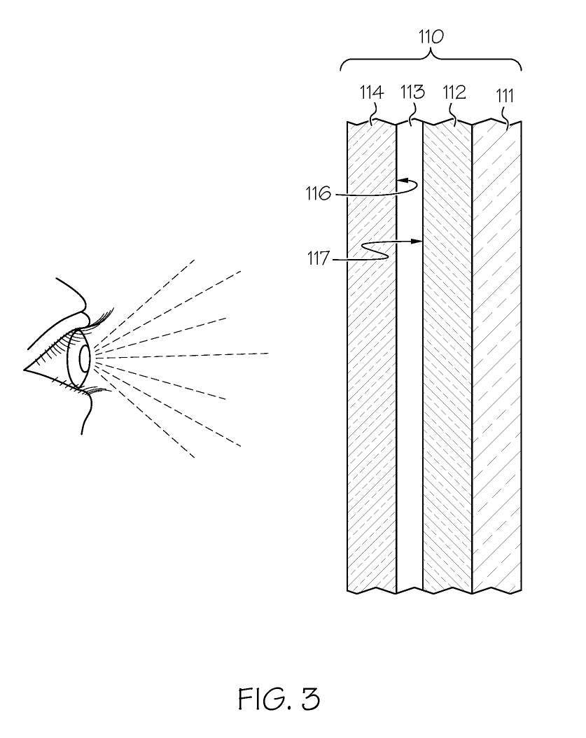

FIG. 3 shows an alternative embodiment of the present invention in which the rear surface of the flexible display is conductive and is used as the front element of a touch screen. FIG. 3 shows a display system 110 including a backing 111 and a front-mounted flexible display 114. The backing 111 provides a rigid substrate or base upon which the other components are mounted. The backing 111 preferably is opaque. A touch-screen can comprise the rear surface 116 of the front-mounted flexible display 114, an air gap 113, and the rear panel 112. The front-mounted flexible display 114 is flexible enough and positioned close enough to the rear panel 112 that touching the front-mounted flexible display 114 causes enough deflection of the front-mounted display to cause it to bridge the air gap locally and to contact the front surface 117 of rear panel 112. Thus, in this way the electrical path (and therefore the resistance of the circuit) can be mapped to the particular location on the touch-screen/front-mounted display touched by the user.

Optionally, the touch-screen 20 can comprise a resistive touch-screen which is adapted to receive, during use, a selection of a item displayed by the flexible display 16 or other input provided by a user through the application of pressure to the flexible display 16 with a finger, stylus, or other selection or pointing device, and to produce a voltage division representative of the x-y location of the applied pressure to connected (via interface wires not shown) electrical circuitry in a manner similar to conventional resistive touch-screen devices.

In one example form, a touch-screen front layer provides a substrate for the touch front resistive surface and has, according to the first exemplary embodiment, a thickness in the front-to-back direction measuring approximately 0.2 millimeters. The thickness of the touch front layer is selected so as to enable the touch front layer to deflect or flex, when the display system is in use and a displayed item is selected by a user, by an amount sufficient to cause the touch front resistive surface and touch rear resistive surface to come into contact with one another. Thus, it should be noted that the touch front layer might have different thicknesses in different implementations of the display system as is necessary to enable sufficient deflection or flexing thereof.

A touch-screen rear layer is positioned rearward of and substantially parallel to the touch front layer. Generally, the touch rear layer has a thickness in the front-to-back direction that is selected so as to resist appreciable deflection, or flexing, during a user's selection of an item displayed by the display system. According to an exemplary embodiment, the touch rear layer has a thickness of approximately 3 millimeters. It should be noted, however, that the thickness of the touch rear layer might have other measures in other embodiments of the present invention.

The touch front resistive surface is applied and secured to the back surface of the touch front layer such that the touch front resistive surface deflects, or flexes, in substantial unison with the touch front layer during a user's selection of an item displayed by the display system. The touch rear resistive surface is applied and secured to the front surface of the touch rear layer, but due at least in part to the rigidity and thickness of the touch rear layer, the deflection or flexing of the touch rear resistive surface is limited and minimized during a user's selection of an item displayed by the display system. Respectively, the touch front and rear resistive surfaces comprise front and rear resistive elements of the display system's resistive touch-screen portion that function in a manner that is substantially similar to resistive surfaces in common resistive touch-screen devices. For example, typically, the touch front and rear resistive surfaces each have an indium-tin oxide coating.

Optionally, the resistive touch-screen portion 20 can further comprise a plurality of touch spacers that are interposed between the touch front and rear resistive surfaces. Such touch spacers can be operative to prevent the touch front resistive surface and the touch rear resistive surface from coming into contact absent intentional deflection or flexing of the touch front layer. Generally, such touch spacers are manufactured from a material that is electrically non-conductive.

Further, while examples of the present invention are described herein in connection with a resistive touch-screen, other touch-screen technologies can be employed as well.

Also optionally, various coatings, anti-reflective technologies and other optical technologies can be applied to the front surface of the display, as desired. For example, optionally, for glare reduction, the flexible cover layer 30 can comprise opposed first and second quarter wave plates that are generally adapted to cancel glare and allow the passage of light therethrough with minimal light absorption. Also optionally, polarizers could be employed in some applications. Likewise, the display can be adapted to respond to different or variable ambient lighting conditions, such as are often experienced in ground vehicles or aircraft. The display further can comprise an electromagnetic interference (EMI) shield if desired.

It is to be understood that this invention is not limited to the specific devices, methods, conditions, or parameters described and/or shown herein, and that the terminology used herein is for the purpose of describing particular embodiments by way of example only. Thus, the terminology is intended to be broadly construed and is not intended to be limiting of the claimed invention. For example, as used in the specification including the appended claims, the singular forms “a,” “an,” and “one” include the plural, the term “or” means “and/or,” and reference to a particular numerical value includes at least that particular value, unless the context clearly dictates otherwise. In addition, any methods described herein are not intended to be limited to the sequence of steps described but can be carried out in other sequences, unless expressly stated otherwise herein.

While the invention has been shown and described in exemplary forms, it will be apparent to those skilled in the art that many modifications, additions, and deletions can be made therein without departing from the spirit and scope of the invention as defined by the following claims.

1. A display system comprising:
a touch-screen; and
a thin, flexible LED display mounted in front of the touch-screen and being flexible enough to allow a user to touch the thin, flexible LED display and to operate the touch-screen behind the thin, flexible LED display by deflecting the thin, flexible LED display.

2. The display system as claimed in claim 1 wherein the touch-screen is a pressure sensitive touch-screen.

3. The display system as claimed in claim 2 wherein the touch-screen includes first and second panels separated by an air gap.

4. The display system as claimed in claim 1 wherein the thin, flexible LED display comprises a metalized polymer display.

5. The display system as claimed in claim 1 wherein the touch-screen is mounted to a rigid backing and the thin, flexible LED display is mounted to the touch-screen.

6. The display system as claimed in claim 1 further comprising a protective transparent cover in front of the thin, flexible LED display.

7. The display system as claimed in claim 1 wherein the touch-screen rear panel is mounted to a rigid backing.

8. A display system comprising:
a touch-screen integrated with a thin, flexible LED display and wherein a rear surface of the thin, flexible LED display serves as a front panel of the touch-screen, and wherein the thin, flexible LED display is mounted in front of the touch-screen rear panel and is flexible enough to allow a user to touch the thin, flexible LED display and to operate the touch-screen.

9. The display system as claimed in claim 8 wherein the touch-screen is a pressure sensitive touch-screen.

10. The display system as claimed in claim 8 wherein rear surface of the thin, flexible display is separated from the touch-screen rear panel by an air gap.

11. In a display system of the type having a display for viewing by a user and coupled with a touch-screen for input by the user, the improvement therein comprising that the display comprises a thin, flexible display positioned in front of the touch-screen, rather than behind the touch-screen, wherein the touch-screen is operated by touching the thin, flexible display.

12. The display system as claimed in claim 1 wherein the thin, flexible LED display comprises a metallic display.

13. In a display system of the type having a touch-screen and a display associated with the touch-screen, the improvement therein comprising:
that the touch-screen has a rear panel and that the display is a thin, flexible display and a rear surface of the thin, flexible display functions as a front panel of the touch-screen, and wherein the thin, flexible display is mounted in front of the touch-screen rear panel and is flexible enough to allow a user to touch the thin, flexible display and to operate the touch-screen by causing the rear surface of the thin, flexible display to contact a surface of the rear panel of the touch-screen.

14. The improvement in a display system as claimed in claim 13 wherein the thin, flexible display comprises an LED display.

15. The improvement in a display system as claimed in claim 14 wherein the thin, flexible LED display comprises a metallic display.

16. The improvement in a display system as claimed in claim 14 wherein the thin, flexible display comprises a metalized polymer display.
